(19) United States
(12) Patent Application Publication
(10) Pub. No.: US 2024/0258926 A1
(43) Pub. Date: Aug. 1, 2024

(54) ADAPTIVE CLAMP THRESHOLD

(71) Applicant: TEXAS INSTRUMENTS INCORPORATED, Dallas, TX (US)

(72) Inventors: Joseph Maurice KHAYAT, Bedford, NH (US); Wei DA, Manchester, NH (US)

(21) Appl. No.: 18/168,986

(22) Filed: Feb. 14, 2023

Related U.S. Application Data
(60) Provisional application No. 63/441,679, filed on Jan. 27, 2023.

(51) Int. Cl. H02M 3/158; H02M 1/00; H02M 1/096; H02M 1/42

(52) U.S. Cl. CPC H02M 3/1584; H02M 1/0009; H02M 1/096; H02M 1/42; H03K 17/0822

(57) ABSTRACT

In some examples, an apparatus includes a tuning circuit having a tuning output and first, second, third, fourth, and fifth tuning inputs, wherein the first tuning input is coupled to a sensor input terminal, the second tuning input is coupled to a first sensor threshold terminal, and the third tuning input is coupled to a second sensor threshold terminal, an avalanche diode having a first anode and a first cathode, wherein the first cathode is coupled to a power terminal, and the first anode is coupled to the fourth tuning input, a diode having a second anode and a second cathode, a transistor coupled between the power terminal and the second anode and having a control terminal coupled to the tuning output, and a timeout circuit having a timeout input coupled to the tuning output, and a timeout output coupled to the fifth tuning input.

### CROSS-REFERENCE TO RELATED APPLICATIONS

The present application claims priority to U.S. Provisional Patent Application No. 63/441,679, which was filed Jan. 27, 2023, is titled “Adaptive Power FET Vds Clamp Threshold,” and is hereby incorporated herein by reference in its entirety.

### BACKGROUND

In various electronic devices, voltages are provided at a node or terminal of a circuit. One example of such a circuit is a power converter. To maintain the node or terminal within a safe operating range specified for the circuit, the circuit may include, or be coupled to, a clamp circuit at the node or terminal. The clamp circuit may restrict a maximum value voltage that may be provided at the node or terminal. Various challenges may arise in implementing the clamp circuit.

### SUMMARY

In some examples, an apparatus includes a tuning circuit, an avalanche diode, a diode, a transistor, and a timeout circuit. The tuning circuit has a tuning output and first, second, third, fourth, and fifth tuning inputs, in which the first tuning input is coupled to a sensor input terminal, the second tuning input is coupled to a first sensor threshold terminal, and the third tuning input is coupled to a second sensor threshold terminal. The avalanche diode has a first anode and a first cathode, in which the first cathode is coupled to a power terminal, and the first anode is coupled to the fourth tuning input. The diode has a second anode and a second cathode. The transistor has a control terminal, the transistor coupled between the power terminal and the second anode, and the control terminal coupled to the tuning output. The timeout circuit has a timeout input and a timeout output, the timeout input coupled to the tuning output, and the timeout output coupled to the fifth tuning input.

In some examples, an apparatus includes a power terminal at which a voltage is provided, and a clamp circuit. The clamp circuit is configured to clamp an upper limit of a value range for the voltage to a clamp threshold value. The clamp circuit includes an avalanche diode, a tuning circuit, a diode, a transistor, and a timeout circuit. The tuning circuit has a tuning output and first, second, third, fourth, and fifth tuning inputs, in which the first tuning input is coupled to a sensor input terminal, the second tuning input is coupled to a first sensor threshold terminal, the third tuning input is coupled to a second sensor threshold terminal, the fourth tuning input is coupled to the avalanche diode. The avalanche diode is coupled between the power terminal and the tuning circuit. The tuning circuit is configured to modify the clamp threshold value responsive to a sensor measurement signal at the sensor input terminal being outside a range bounded by a first sensor threshold signal at the first sensor threshold terminal and a second sensor threshold signal at the second sensor threshold terminal. The transistor has a control terminal, the transistor coupled between the power terminal and the diode, and the control terminal coupled to the tuning output. The timeout circuit has a timeout input and a timeout output, in which the timeout input is coupled to the tuning output, the timeout output is coupled to the fifth tuning input. The timeout circuit is configured to detect whether the clamp circuit is clamping the voltage to the clamp threshold value, and increase the clamp threshold value an amount of time after detecting that the clamp circuit is clamping the voltage to the clamp threshold value.

In some examples, a system includes a switched-mode power supply, including a low-side transistor having a power control terminal and a clamp circuit. The low-side transistor is coupled between a switch terminal and a ground terminal. The clamp circuit includes an avalanche diode, a tuning circuit, a diode, a transistor, and a timeout circuit. The tuning circuit has a tuning output and first, second, third, fourth, and fifth tuning inputs, in which the first tuning input is coupled to a sensor input terminal, the second tuning input is coupled to a first sensor threshold terminal, the third tuning input is coupled to a second sensor threshold terminal, and the fourth tuning input is coupled to the avalanche diode. The avalanche diode is coupled between the switch terminal and the tuning circuit. The transistor has a control terminal, the transistor coupled between the power control terminal and the diode, the control terminal coupled to the tuning output, and the diode coupled between the transistor and the power control terminal. The timeout circuit has a timeout input and a timeout output, the timeout input coupled to the tuning output and the timeout output coupled to the fifth tuning input.

### BRIEF DESCRIPTION OF THE DRAWINGS

FIG. 1 is a schematic diagram of a system, in accordance with various examples.

FIG. 2 is a schematic diagram of a tuning circuit, in accordance with various examples.

FIG. 3 is a schematic diagram of a tuning circuit, in accordance with various examples.

FIG. 4 is a schematic diagram of a timeout circuit, in accordance with various examples.

FIG. 5 is a diagram of signals, in accordance with various examples.

FIG. 6 is a diagram of signals, in accordance with various examples.

FIG. 7 is a flow diagram of a method, in accordance with various examples.

### DETAILED DESCRIPTION

As described above, in various electronic devices, voltages are provided at a node or terminal of a circuit. One example of such a circuit is a power converter, in which the node or terminal is a switch node of the power converter and is coupled to a power device (e.g., transistor) of the power converter. To maintain the voltage provided at the node or terminal (and therefore, the power device) within a safe operating range specified for the circuit, the circuit may include, or be coupled to, a clamp circuit at the node or terminal. The clamp circuit may restrict a maximum value of the voltage provided at the node or terminal. Various challenges may arise in implementing the clamp circuit. For example, temperature and process variation of components of the clamp circuit may result in the clamp being overdesigned. As used herein, the clamp circuit being overdesigned includes the clamp circuit implemented with high-voltage rated power devices having a safe operating area beyond that of the power device being protected and/or the programmed clamp voltage of the clamp circuit.

Examples of this description provide for a clamp circuit, such as may be useful for clamping a voltage at a node or terminal of a circuit. In some examples, the clamp circuit is tunable such that a clamp threshold (e.g., a voltage to which the clamp circuit clamps the node or terminal) is adjustable based on operating conditions of the circuit. For example, the clamp circuit may include a tuning circuit for modifying the clamp threshold based on a detected temperature, or any other suitable sensor output. Responsive to the sensor output having a value greater than a reference threshold, the clamp threshold may be modified in a first direction (e.g., decreased or increased). Responsive to the sensor output having a value lesser than the reference threshold, the clamp threshold may be modified in a second direction (e.g., increased or decreased). In some examples, the clamp circuit also includes a timeout circuit. Responsive to activation of the clamp circuit, the timeout circuit may monitor an amount of time elapsed since the activation. Responsive to the amount of time exceeding a time threshold, the timeout circuit may cause the clamp circuit to increase the clamp threshold, for example, thus releasing the activation at the lower clamp threshold.

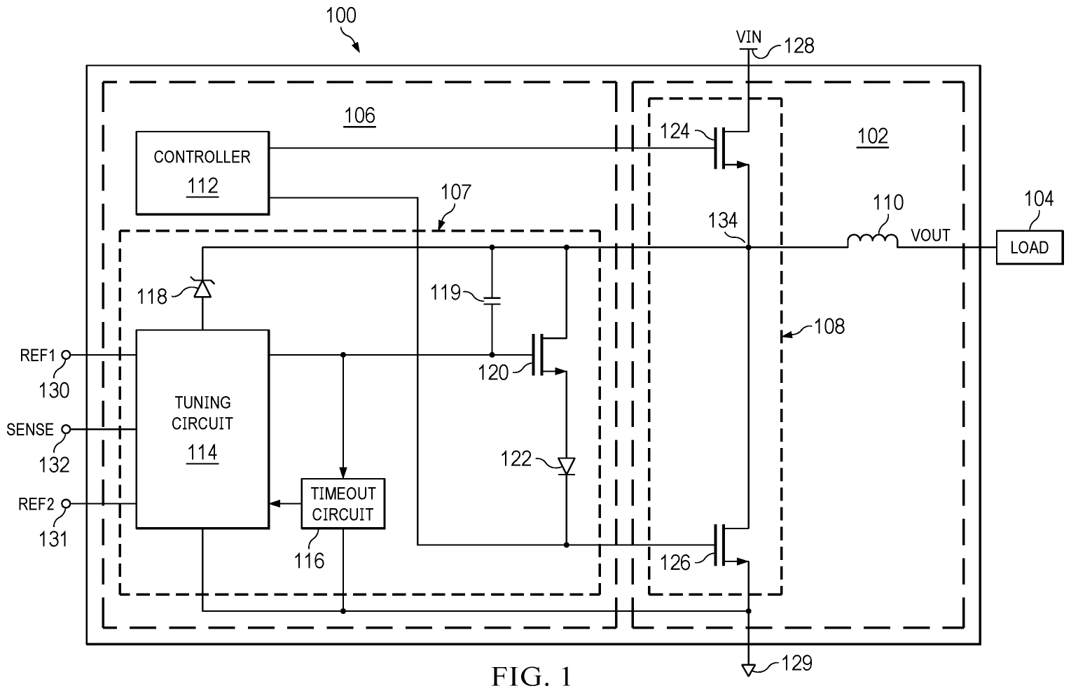

FIG. 1 is a schematic diagram of a system 100, in accordance with various examples. The system 100 is representative of an application environment in which power is provided by a power converter 102 to a load 104. For example, the system 100 is representative of an automobile or other vehicle, a computing device such as a laptop, a notebook, a server, a smartphone, a tablet, a wearable device, or the like. The system 100 may include a switch mode power supply (SMPS) or other power supply, etc. In an example, the system 100 includes the power converter 102, the load 104, and control circuitry 106. In an example, the power converter 102 is a switching regulator that includes a switching circuit 108 and an energy storage component 110. The control circuitry 106 includes a controller 112, a tuning circuit 114, a timeout circuit 116, a diode 118, a capacitor 119, a transistor 120, and a diode 122. Some examples of the system 100 also include a gate driver (not shown), which may be incorporated into the power converter 102 or the control circuitry 106. The switching circuit 108 includes a transistor 124 and a transistor 126. In an example, the controller 112 includes any suitable analog, digital, or combination thereof, components for implementing a circuit architecture suitable for determining values of, and providing, gate control signals to the power converter 102 for controlling switching of the transistor 124 and/or the transistor 126. In some examples, the controller 112 includes, or is coupled to, a gate driver (not shown) for controlling switching of the transistor 124 and/or the transistor 126. In an example, the tuning circuit 114, the timeout circuit 116, the diode 118, the transistor 120, and the diode 122, together form a clamp architecture or clamp circuit 107 configured to clamp a voltage provided at the node 134 to a programmed clamp threshold. In some examples, the clamp threshold is modifiable, such as by the tuning circuit 114.

In an example architecture of the system 100, the power converter 102 has a first input coupled to a voltage source 128, a second input, and an output. The load 104 has an input coupled to the output of the power converter 102. The control circuitry 106 has a first input coupled to the power converter 102, and a first output coupled to the power converter 102. For example, the transistor 124 has a drain coupled to the voltage source 128, a gate, and a source. The transistor 126 has a drain coupled to the source of the transistor 124, a gate, and a source coupled to a ground terminal 129. The energy storage component 110 is coupled between the source of the transistor 124 and an output terminal of the power converter 102 (e.g., to which the load 104 couples). The controller 112 has an output coupled to the gate of the transistor 124 and may have any suitable number of inputs (not shown) based on an architecture of the controller 112. The tuning circuit 114 has a first input coupled to a first reference terminal 130, a second input coupled to a second reference terminal 131, a third input coupled to a sensor terminal 132, a fourth input coupled to the timeout circuit 116, a first output, and a second output. The timeout circuit 116 has an input coupled to the gate of the transistor 120 and an output coupled to the fourth input of the tuning circuit 114. The diode 118 has an anode coupled to the first output of the tuning circuit 114 and a cathode coupled to the source of the transistor 124. In an example, the diode 118 is a Zener or an avalanche diode. The transistor 120 has a drain coupled to the source of the transistor 124, a gate coupled to the second output of the tuning circuit 114, and a source. The capacitor 119 is coupled between the node 134 and the gate of the transistor 120. The diode 122 has an anode coupled to the source of the transistor 120 and a cathode coupled to the gate of the transistor 126.

In an example of operation of the system 100, the power converter 102 switches an input voltage (VIN) provided by the voltage source 128 to provide an output voltage (VOUT) to the load 104. A sensor (not shown in FIG. 1), processor, microprocessor, controller, or the like may monitor an aspect of the system 100, such as a temperature, a pressure, a voltage, a current, or the like and provide a signal (a sensor signal) representative of, or determined based on, the monitored aspect at the sensor terminal 132. In some examples, the tuning circuit 114 compares the sensor signal (SENSE) to a first reference signal (REF1) provided at the first reference terminal 130 and a second reference signal (REF2) provided at the second reference terminal 131. Responsive to the sensor signal exceeding the first reference signal, the tuning circuit 114 activates and modifies (e.g., reduces) its resistance as provided at the gate of the transistor 120 to decrease the clamp threshold. Similarly, responsive to the sensor signal exceeding the second reference signal, the tuning circuit 114 activates and modifies (e.g., decreases) its resistance as provided at the gate of the transistor 120 to increase the clamp threshold. In other examples, the tuning circuit 114 compares SENSE to any other suitable number of reference signals, such as one reference signal or more than two reference signals and modifies the clamp threshold based on an outcome of any number of those comparisons.

Responsive to the sensor signal reverting to its prior state (e.g., becoming less than the first reference signal or greater than the second reference signal), the tuning circuit 114 modifies its resistance as provided at the gate of the transistor 120 to return the clamp threshold to its normal state. For example, responsive to the sensor signal becoming greater in value than the first reference signal, the tuning circuit 114 modifies its resistance as provided at the gate of the transistor 120 to reduce the effective clamp threshold lower than its normal state. Responsive to the sensor signal becoming lesser in value than the second reference signal, the tuning circuit 114 modifies its resistance as provided at the gate of the transistor 120 to increase the effective clamp threshold higher than its normal state.

Responsive to activation of the tuning circuit 114, the timeout circuit 116 activates. The timeout circuit 116 provides a signal (TIME) having an asserted value to the tuning circuit 114 responsive to a programmed amount of time passing since activation of the timeout circuit 116. For example, the timeout circuit 116 may be programmed to provide the signal having the asserted value approximately 10 nanoseconds (ns). In other examples, the programmed amount of time may be any other suitable amount, such as greater or less than 10 ns. In some examples, providing the signal having the asserted value to the tuning circuit 114 causes the tuning circuit 114 to change its resistance as provided at the gate of the transistor 120 to increase the effective clamp threshold higher than its normal level, thus releasing the activation at the normal level.

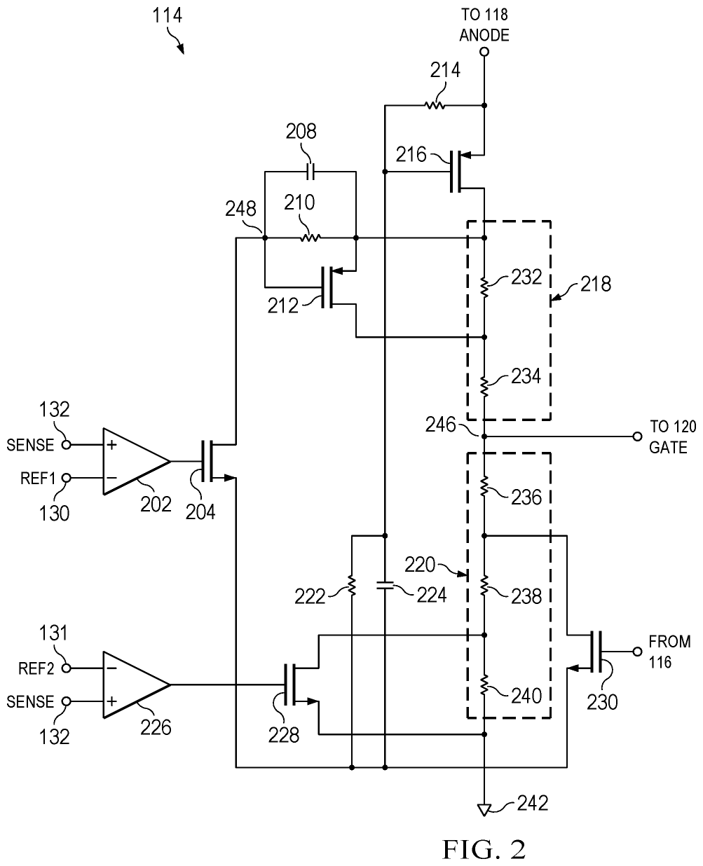

FIG. 2 is a schematic diagram of the tuning circuit 114, in accordance with various examples. In an example, the tuning circuit 114 includes a comparator 202, a transistor 204, a capacitor 208 and a resistor 210, a transistor 212, a resistor 214, a transistor 216, a first resistive circuit 218, a second resistive circuit 220, a resistor 222, a capacitor 224, a comparator 226, a transistor 228, and a transistor 230.

In an example architecture of the tuning circuit 114 of FIG. 2, the comparator 202 has a first input (e.g., a positive or non-inverting input) coupled to the sensor terminal 132, a second input (e.g., a negative or inverting input) coupled to the first reference terminal 130, and an output. The transistor 204 has a gate coupled to the output of the comparator 202, a source coupled to a ground terminal 242, and a drain. The transistor 212 has a gate coupled to the drain of the transistor 204, a source, and a drain. The capacitor 208 and the resistor 210 are coupled in parallel between the gate and the source of the transistor 212. The transistor 216 has a drain coupled to the source of the transistor 212, a gate, and a source. The resistor 214 is coupled between the source and the gate of the transistor 216. In some examples, the transistor 216 couples at its source to the anode of the diode 118. The first resistive circuit 218 and the second resistive circuit 220 are coupled in series between the drain of the transistor 216 and the ground terminal 242. The resistor 222 and the capacitor 224 are coupled in parallel between the gate of the transistor 216 and the ground terminal 242. The comparator 226 has a first input (e.g., a positive or non-inverting input) coupled to the first reference terminal 130, a second input (e.g., a negative or inverting input) coupled to the second reference terminal 131, and an output. The transistor 228 has a gate coupled to the output of the comparator 226, a source coupled to the ground terminal 242, and a drain. The transistor 230 has a gate, a source coupled to the ground terminal 242, and a drain. In some examples, the transistor 230 couples at its gate to the timeout circuit 116. In some examples, the first resistive circuit 218 has a resistor 232 coupled between the source and drain of the transistor 212 and a resistor 234 coupled between the drain of the transistor 212 and a node 246. In some examples, the second resistive circuit 220 includes a resistor 236 coupled between the node 246 and the drain of the transistor 230, a resistor 238 coupled between the drain of the transistor 230 and the drain of the transistor 228, and a resistor 240 coupled between the drain and the source of the transistor 228. While each of the resistors 232-240 are shown in FIG. 2 as singular discrete components, in various examples any of the resistors 232-240 may be replaced by any other component or combination of components that provide a programmed or controllable amount of resistance, such as a series or parallel combination of discrete resistors, an adjustable or programmable resistor, a voltage-controlled resistor (VCR), such as implemented as a transistor, a current-controlled resistor (CCR), or any other suitable component(s) that provide a programmed or controllable amount of resistance.

In an example of operation of the tuning circuit 114 of FIG. 2, the tuning circuit 114 modifies a ratio of resistance provided at the node 246 (which may be the resistance of the tuning circuit 114 as provided at the gate of the transistor 120, described above with respect to FIG. 1), such as responsive to a change in value of SENSE with respect to REF1 or REF2, or responsive to assertion of TIME. In an example, responsive to SENSE exceeding REF1, the tuning circuit 114 modifies the ratio of resistance provided at the node 246. For example, responsive to SENSE exceeding REF1, the comparator 202 provides a signal having an asserted value. The asserted value provided by the comparator 202 causes the transistor 204 to become conductive, pulling the node 248 down to a potential as provided by the ground terminal 242, through the transistor 204. Responsive to the node 248 being pulled down to a voltage sufficient to cause the transistor 212 to become conductive, the transistor 212 shorts the resistor 232 by creating a path through the transistor 212 having less resistance than that of the resistor 232. The first resistive circuit 218 and the second resistive circuit 220 form a resistor divider having an output at the node 246. As such, shorting the resistor 232 causes the ratio of resistance of the tuning circuit 114 as provided at the node 246 to decrease in comparison to the ratio of resistance of the tuning circuit 114 as provided at the node 246 while the resistor 232 is not shorted.

Similarly, responsive to REF2 exceeding SENSE, the tuning circuit 114 modifies the ratio of resistance provided at the node 246. For example, responsive to REF2 exceeding SENSE, the comparator 226 provides a signal having an asserted value. The asserted value provided by the comparator 226 causes the transistor 228 to become conductive, shorting the resistor 240 by creating a path through the transistor 228 having less resistance than that of the resistor 240. Because the first resistive circuit 218 and the second resistive circuit 220 form a resistor divider having an output at the node 246, shorting the resistor 240 causes the ratio of resistance of the tuning circuit 114 as provided at the node 246 to increase in comparison to the ratio of resistance of the tuning circuit 114 as provided at the node 246 while the resistor 240 is not shorted.

Responsive to SENSE decreasing in value to be less than REF1, the comparator 202 provides a signal having a de-asserted value to cause the transistor 204, and therefore the transistor 212, to become nonconductive. The transistor 212 becoming nonconductive may remove the short of the resistor 232, increasing the ratio of resistance provided at the node 246. Similarly, responsive to SENSE increasing in value to be greater than REF2, the comparator 226 provides a signal having a de-asserted value to cause the transistor 228 to become nonconductive. The transistor 228 becoming nonconductive may remove the short of the resistor 240, decreasing the ratio of resistance provided at the node 246.

In some examples, the ratio of resistance provided at the node 246 may also be decreased by the timeout circuit 116. For example, responsive to assertion of TIME, the transistor 230 may become conductive, shorting the resistors 238, 240 by creating a path through the transistor 230 having less resistance than the combined resistance of the resistors 238, 240. Responsive to de-assertion of TIME the transistor 230 may become nonconductive. The transistor 230 becoming nonconductive may remove the short of the resistors 238, 240, decreasing the ratio of resistance provided at the node 246.

In an example, the capacitor 208 mitigates parasitic coupling of the resistor 210 as a voltage provided at the anode of the diode 118 varies. The resistor 214 and the capacitor 224 form a filter having a time constant that controls a rate of rise and fall of the voltage provided at the gate of the transistor 216. The resistor 222 provides a bleed, or discharge, path for discharge of the capacitor 224.

In some examples, the ratio of resistance provided at the node 246 provides a gain factor for determining the clamp threshold. For example, as the ratio of resistance provided at the node 246 increases, the clamp threshold increases. Similarly, as the ratio of resistance provided at the node 246 decreases, the clamp threshold decreases. In an example, the clamp threshold (V_CLAMP), to which the clamp circuit 107 including the tuning circuit 114 of FIG. 2 may clamp the node 134 (e.g., a switch node of the power converter 102) is determined according to the following equation 1. In equation 1, R232 is the resistance of the resistor 232, R234 is the resistance of the resistor 234, Rx=(R232+R234), R236 is the resistance of the resistor 236, R238 is the resistance of the resistor 238, R240 is the resistance of the resistor 240, Ry=(R236+R238+R240), V118 is a diode voltage of the diode 118, V120 is a gate-to-source voltage of the transistor 120, V122 is a diode voltage of the diode 122, V126 is a gate-to-source voltage of the transistor 126, and V216 is a drain-to-source voltage of the transistor 216.

$$V\_CLAMP = V 118 + V 2 \; 16 + ( 1 + Rx / Ry ) * ( V 120 + V 126 + V 122 ) \qquad ( 1 )$$

Modifying the ratio of resistance of the tuning circuit 114 is described with respect to FIG. 2 as decreasing the ratio by shorting a resistor of the first resistive circuit 218 and increasing the ratio by shorting a resistor of the second resistive circuit 220. However, although not shown in FIG. 2, the reverse may also be implemented in various examples. For example, the ratio of resistance of the tuning circuit 114 as provided at the node 246 may be decreased by releasing the shorting of a resistor of the second resistive circuit 220 (increasing a resistance of the second resistive circuit 220) and may be increased by releasing the shorting of a resistor of the first resistive circuit 218 (e.g., increasing a resistance of the first resistive circuit 218).

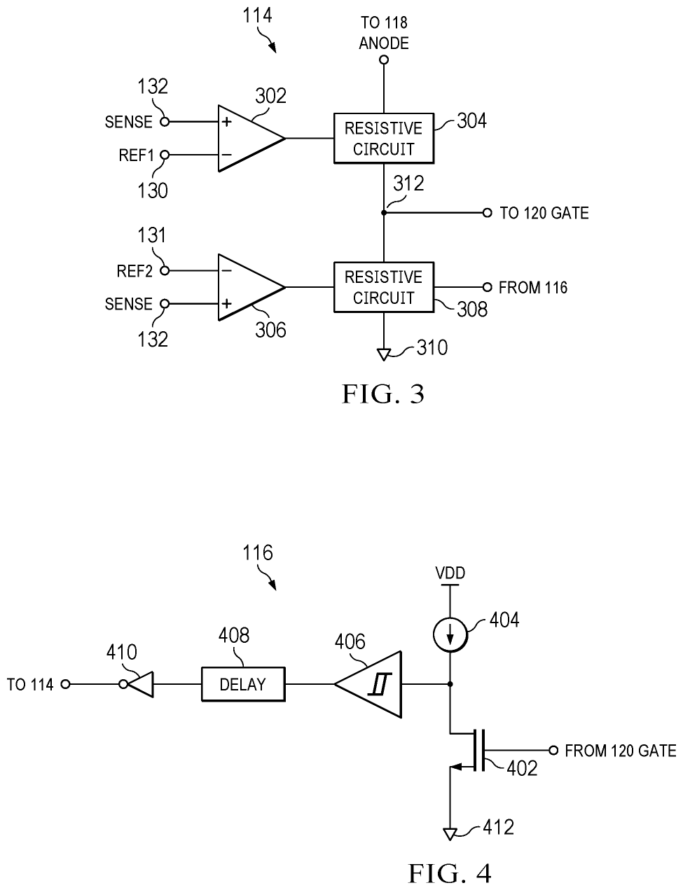

FIG. 3 is a schematic diagram of the tuning circuit 114, in accordance with various examples. In an example, the tuning circuit 114 includes a comparator 302, a resistive circuit 304, a comparator 306, and a resistive circuit 308. In an example architecture of the tuning circuit 114 of FIG. 3, the comparator 302 has a first input (e.g., a positive or non-inverting input) coupled to the sensor terminal 132, a second input (e.g., a negative or inverting input) coupled to the first reference terminal 130, and an output. The resistive circuit 304 as a first input coupled to the output of the comparator 302, a second input, and an output. In some examples, the resistive circuit 304 couples at its second input to the anode of the diode 118. The comparator 306 has a first input (e.g., a positive or non-inverting input) coupled to the sensor terminal 132, a second input (e.g., a negative or inverting input) coupled to the second reference terminal 131, and an output. The resistive circuit 308 has a first input coupled to the output of the comparator 306, a second input coupled to the output of the resistive circuit 304, a third input, and an output coupled to a ground terminal 310. In some examples, the resistive circuit 304 couples at its third input to the timeout circuit 116. In some examples, the tuning circuit 114 couples at a node 312 (e.g., the output of the resistive circuit 304 and the second input of the resistive circuit 308) to the gate of the transistor 120.

In an example of operation of the tuning circuit 114 of FIG. 3, the tuning circuit 114 modifies a ratio of resistance provided at the node 312, such as responsive to a change in value of SENSE with respect to REF1 or REF2, or responsive to assertion of TIME. In an example, responsive to SENSE exceeding REF1, the tuning circuit 114 modifies the ratio of resistance provided at the node 312. For example, responsive to SENSE exceeding REF1, the comparator 302 provides a signal having an asserted value. The asserted value provided by the comparator 302 causes a resistance of the resistive circuit 304 to decrease. The resistive circuit 304 and the resistive circuit 308 form a resistor divider having an output at the node 312. As such, decreasing the resistance of the resistive circuit 304 causes the ratio of resistance of the tuning circuit 114 as provided at the node 312 to decrease.

Similarly, responsive to REF2 exceeding SENSE, the tuning circuit 114 modifies the ratio of resistance provided at the node 312. For example, responsive to REF2 exceeding SENSE, the comparator 306 provides a signal having an asserted value. The asserted value provided by the comparator 306 causes a resistance of the resistive circuit 308 to decrease. Because the resistive circuit 304 and the resistive circuit 308 form a resistor divider having an output at the node 312, decreasing the resistance of the resistive circuit 308 causes the ratio of resistance of the tuning circuit 114 as provided at the node 312 to increase.

In various examples, the resistive circuit 304 and the resistive circuit 308 may each include any suitable components controllable to modify or program a resistance presented or provided by the resistive circuit 304 and the resistive circuit 308, respectively. For example, the resistive circuit 304 and the resistive circuit 308 may each include any suitable combination of discrete components (such as resistors), switches, VCRs, such as implemented as a transistor, CCRs, or any other suitable component(s) that provide a programmed or controllable amount of resistance. Although not shown in FIG. 3, in some examples, the comparator 302 and the comparator 306 are omitted, such as in examples in which the resistive circuit 304 and the resistive circuit 308 are coupled to a processor, controller, or other circuitry that provides signals having values (e.g., voltage or current) for programming the resistive circuit 304 and/or the resistive circuit 308 to provide a programmed amount of resistance.

In some examples, the ratio of resistance provided at the node 312 provides a gain factor for determining V_CLAMP, as described above. For example, as the ratio of resistance provided at the node 312 increases, V_CLAMP increases. Similarly, as the ratio of resistance provided at the node 312 decreases, V_CLAMP decreases. In an example, V_CLAMP, to which the clamp circuit 107 including the tuning circuit 114 of FIG. 3 may clamp the node 134 (e.g., a switch node of the power converter 102) is determined according to the following equation 2. In equation 2, R304 is the resistance of the resistive circuit 304, R308 is the resistance of the resistive circuit 308, and V118, V120, V122, and V126 are as described above with respect to equation 1.

$$V\_CLAMP = V 118 + ( 1 + R 304 / R 3 \; 08 ) * ( V 120 + V 126 + V 122 ) \qquad ( 2 )$$

Responsive to SENSE decreasing in value to be less than REF1, the comparator 302 provides a signal having a de-asserted value to cause the resistance of the resistive circuit 304 to increase, increasing the ratio of resistance provided at the node 312. Similarly, responsive to SENSE increasing in value to be greater than REF2, the comparator 306 provides a signal having a de-asserted value to cause the resistance of the resistive circuit 308 to increase, decreasing the ratio of resistance provided at the node 312. In some examples, the ratio of resistance provided at the node 312 may also be decreased by the timeout circuit 116. For example, responsive to assertion of TIME, the resistance of the resistive circuit 308 may decrease, increasing the ratio of resistance provided at the node 246.

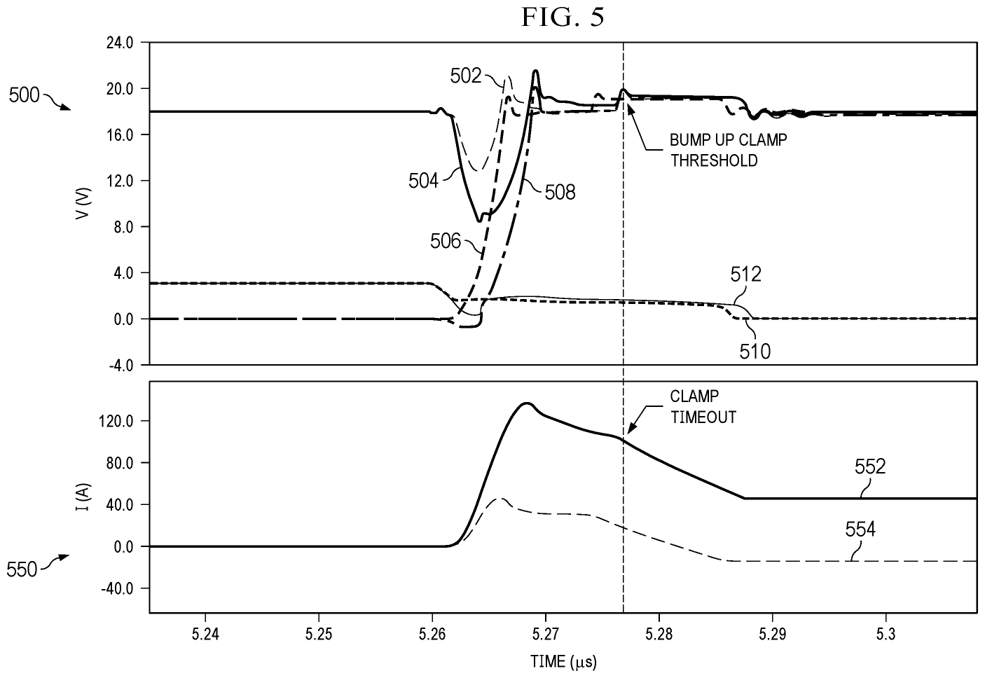

FIG. 4 is a schematic diagram of the timeout circuit 116, in accordance with various examples. In an example, the timeout circuit 116 includes a transistor 402, a current source 404, a Schmitt trigger 406, a delay circuit 408, and an inverter 410. In an example architecture of the timeout circuit 116, the transistor 402 has a gate, a source coupled to a ground terminal 412, and a drain. In some examples, the gate of the transistor 402 is coupled the gate of the transistor 120. The current source 404 is coupled between a power source 414 that provides a voltage VDD and the drain of the transistor 402. The Schmitt trigger 406 has an input coupled to the drain of the transistor 402 and an output. The delay circuit 408 has an input coupled to the output of the Schmitt trigger 406 and an output. The inverter 410 has an input coupled to the output of the delay circuit 408 and an output. In some examples, the output of the inverter 410 is coupled the tuning circuit 114, such as to provide TIME to the tuning circuit 114, as described above. The delay circuit 408 may have any suitable architecture for implementing a programmed or controllable delay between a rising edge of an input signal and providing an output signal having a corresponding rising edge. In some examples, the delay circuit 408 includes one or more buffers (not shown) coupled serially between the input and the output of the delay circuit 408.

In an example of operation of the timeout circuit 116, responsive to a signal provided at the gate of the transistor 402 exceeding a threshold value for turning on the transistor 402, the transistor 402 becomes conductive. In an example, the transistor 402 becoming conductive indicates that the transistor 120 (e.g., which may be referred to as an active clamp) is active or conductive. The TIME function is intended to limit the active clamp time. Responsive to the transistor 402 becoming conductive, current flows from the current source 404 through the transistor 402 to the ground terminal 412. The current causes a voltage to be provided at the drain of the transistor 402. Responsive to the voltage provided at the drain of the transistor 402 being greater than a threshold of the Schmitt trigger 406, the Schmitt trigger 406 provides an output signal having an asserted value. The delay circuit 408 receives the signal provided by the Schmitt trigger 406 and delays the signal to provide a delayed signal. The inverter 410 inverts a value of the delayed signal and provides that inverted value as TIME having an asserted value.

Responsive to the signal provided at the gate of the transistor 402 not exceeding the threshold value for turning on the transistor 402, the transistor 402 becomes (or remains) nonconductive. Responsive to the transistor 402 being nonconductive, the Schmitt trigger 406 provides a signal having a de-asserted value such that TIME has an asserted value.

Although one architecture for the timeout circuit 116 is shown in FIG. 4, other suitable architectures may also be possible. Generally, the timeout circuit 116 may be implemented via any suitable components capable of receiving an input signal having a first value and providing an output signal having a second value based on the first value, a programmed amount of time after the input signal takes on the first value.

FIG. 5 is a diagram 500 and diagram 550 of signals, in accordance with various examples. In some examples, the diagrams 500 and 550 are representative of signals that may be provided in the system 100, or any of its circuits, and reference may be made to any of the preceding figures of this description in describing the diagram 500 and/or the diagram 550. The diagram 500 is shown having a vertical axis representative of voltage in units of volts (V) and a horizontal axis representative of time in units of microseconds (μs). The diagram 550 is shown having a vertical axis representative of current in units of Amperes (A) and a horizontal axis representative of time in units of μs.

The diagram 500 includes signals 502, 504, 506, 508, 510, and 512. The signal 502 is representative of voltage provided at the drain of the transistor 124 responsive to sinking of current through the energy storage component 110, and caused by a parasitic inductance existing between the drain of the transistor 124 and the voltage source 128. The signal 504 is representative of voltage provided at the drain of the transistor 124 responsive to sourcing of current through the energy storage component 110, and caused by the parasitic inductance existing between the drain of the transistor 124 and the voltage source 128. The signal 506 is representative of a drain-to-source voltage (Vds) of the transistor 126 responsive to sinking of current through the energy storage component 110. The signal 508 is representative of Vds of the transistor 126 responsive to sourcing of current through the energy storage component 110. The signal 510 is representative of a gate-to-source voltage (Vgs) of the transistor 126 responsive to sinking of current through the energy storage component 110. The signal 512 is representative of Vgs of the transistor 126 responsive to sourcing of current through the energy storage component 110. The diagram 550 includes signals 552 and 554. The signal 552 is representative of perturbances of a current sourced from the voltage source 128 for a steady-state load condition (e.g., current flowing through the energy storage component 110) of about 45 A. The signal 554 is representative of perturbances a current sunk to the voltage source 128 for a steady-state load condition of about −15 A.

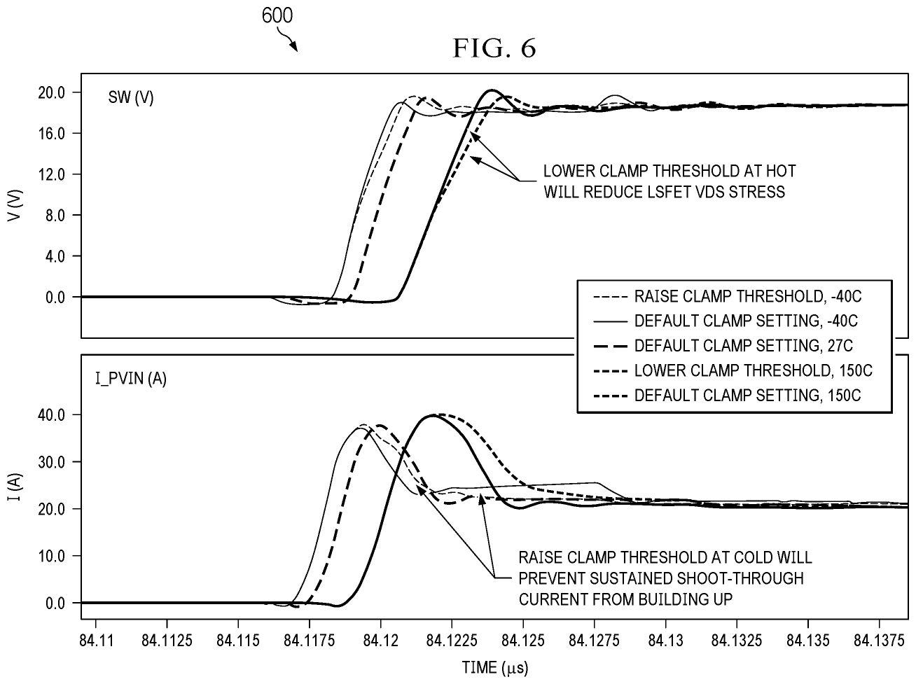

FIG. 6 is a diagram 600 of signals, in accordance with various examples. In an example, the diagram 600 is representative of signals that may be present in the system 100 under various operating conditions. The diagram 600 is shown having a horizontal axis representative of time in units of us and vertical axis representative of voltage in units of V and current in units of A.

In an example, the diagram 600 includes respective signals indicating voltage and current characteristic behavior of the system 100. For example, at nominal operation, represented as operation at about 27 degrees Celsius (27 C), voltage and current characteristics of the system 100 may have respective first values. Responsive to the operating temperature changing, such as to a cold environment, represented as operation at about −40 C, or a hot environment, represented as operations at about 150 C, the clamp threshold may vary in an amount that adversely affects operation of the system 100. However, as further shown by the diagram 600, responsive to modification of the clamp threshold by the clamp circuit 107 via the tuning circuit 114, at least some of the adverse effects of the variation are mitigated. For example, in the hot environment the clamp threshold may be reduced by the clamp circuit 107 and in the cold environment the clamp threshold may be increased by the clamp circuit 107. In at least some examples, the modification of the clamp threshold by the clamp circuit 107 may reduce a drain-to-source voltage of the transistor 126, and therefore reduce electrical overstress on the transistor 126. The modification of the clamp threshold by the clamp circuit 107 may also mitigate the buildup of shoot-through current in the system 100.

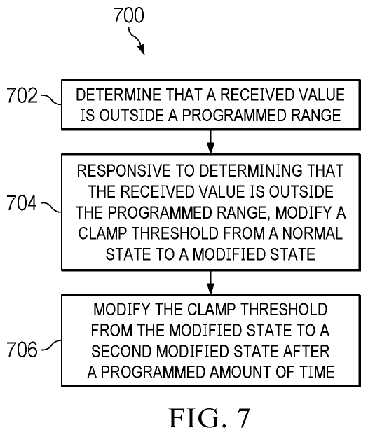

FIG. 7 is a flow diagram of a method 700, in accordance with various examples. In some examples, the method 700 is implemented by the system 100, such as at least in part by the tuning circuit 114 and/or the timeout circuit 116, to increase or decrease a clamp threshold, as described herein.

At operation 702, the system determines that a received value is outside a programmed range. The received value may be, for example, a sensor value. In some examples, the sensor value is a temperature value. In some examples, that programmed range is represented by a threshold value and the received value is outside the programmed range responsive to the received value changing exceeding (in one of a positive or negative direction) the threshold value. In other examples, the received value is determined to be outside the programmed range responsive to the received value being outside a range bounded by a first threshold value (e.g., an upper limit) and a second threshold value (e.g., a lower limit).

At operation 704, responsive to determining that the received value is outside the programmed range, a clamp threshold is modified from a normal state to a modified state. In some examples, the clamp threshold is a voltage to which a clamp circuit clamps a particular node or terminal, such as a switch node of a power converter. In some examples, the clamp threshold is modified by adjusting a resistance of a circuit. In some examples, modifying the resistance modifies a gain factor or resistance ratio of the circuit. Modifying the gain factor may increase or decrease the clamp threshold in an amount based on the modification of the gain factor, such as, in some examples, according to equations 1 or 2, above.

At operation 706, the clamp threshold is modified from the modified state to a second modified state after a programmed amount of time. In some examples, the clamp threshold in the second modified state has a higher value than the clamp threshold in the modified state. In an example, responsive to the programmed amount of time elapsing after the clamp circuit activates and clamps the particular node or terminal to the clamp threshold, the clamp threshold is modified from the modified state to the second modified state. Modifying the clamp threshold from the modified state to the second modified state may cause the clamp circuit to release the clamping of the particular node or terminal.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In this description, the term “couple” may cover connections, communications, or signal paths that enable a functional relationship consistent with this description. For example, if device A provides a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal provided by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter. Modifications are possible in the described examples, and other examples are possible within the scope of the claims.

What is claimed is:

1. An apparatus, comprising:
a tuning circuit having a tuning output and first, second, third, fourth, and fifth tuning inputs, in which the first tuning input is coupled to a sensor input terminal, the second tuning input is coupled to a first sensor threshold terminal, and the third tuning input is coupled to a second sensor threshold terminal;
an avalanche diode having a first anode and a first cathode, in which the first cathode is coupled to a power terminal, and the first anode is coupled to the fourth tuning input;
a diode having a second anode and a second cathode;
a transistor having a control terminal, the transistor coupled between the power terminal and the second anode, and the control terminal coupled to the tuning output; and
a timeout circuit having a timeout input and a timeout output, the timeout input coupled to the tuning output, and the timeout output coupled to the fifth tuning input.

2. The apparatus of claim 1, further comprising a capacitor coupled between the power terminal and the control terminal.

3. The apparatus of claim 1, wherein the tuning circuit includes:
a first comparator having a first comparator output and first and second comparator inputs, the first comparator input coupled to the sensor input terminal, and the second comparator input coupled to the first sensor threshold terminal;
a second comparator having a second comparator output and third and fourth comparator inputs, the third comparator input coupled to the second sensor threshold terminal, and the fourth comparator input coupled to the sensor input terminal;
a second transistor having a second control terminal, the second control terminal coupled to the first comparator output;
a third transistor having a third control terminal, a source, and a drain, wherein the second transistor is coupled between the third control terminal and a ground terminal;
a first resistor coupled between the source and the third control terminal;
a first capacitor coupled between the source and the third control terminal;
a second resistor;
a third resistor coupled between the second resistor and the ground terminal, in which the second resistor is coupled between the first anode and the third resistor;
a second capacitor coupled between the second resistor and the ground terminal;
a fourth transistor having a fourth control terminal, the fourth control terminal coupled to the second resistor, the third resistor, and the second capacitor;
a first resistive circuit having a first resistive output and first and second resistive inputs, in which the first resistive output is coupled to the tuning output, the third transistor is coupled between the first and second resistive inputs, and the fourth transistor is coupled between the avalanche diode and the first resistive input;
a second resistive circuit having a second resistive output and third, fourth, and fifth resistive inputs, in which the second resistive output is coupled to the tuning output, and the third resistive input is coupled to the ground terminal;
a fifth transistor having a fifth control terminal, the fifth transistor coupled between the fourth resistive input and ground, and the fifth control terminal coupled to the second comparator output; and
a sixth transistor having a sixth control terminal, the sixth transistor coupled between the fifth resistive input and ground, and the sixth control terminal coupled to the timeout output.

4. The apparatus of claim 3, wherein:
the first resistive circuit includes:
a fourth resistor coupled between the source and the drain; and
a fifth resistor coupled between the drain and the tuning output; and
the second resistive circuit includes:
a sixth resistor coupled between the tuning output and the fifth resistive input;
a seventh resistor coupled between the fifth resistive input and the fourth resistive input; and
an eighth resistor coupled between the fourth resistive input and the third resistive input.

5. The apparatus of claim 1, wherein the tuning circuit includes:
a first comparator having a first comparator output and first and second comparator inputs, the first comparator input coupled to the sensor input terminal, and the second comparator input coupled to the first sensor threshold terminal;
a second comparator having a second comparator output and third and fourth comparator inputs, the third comparator input coupled to the second sensor threshold terminal, and the fourth comparator input coupled to the sensor input terminal;
a first resistive circuit having a first resistive output and first and second resistive inputs, in which the first resistive input is coupled to the avalanche diode, the second resistive input is coupled to the first comparator output, and the first resistive output is coupled to the tuning output; and
a second resistive circuit having a second resistive output and third and fourth resistive inputs, in which the third resistive input is coupled to a ground terminal, the fourth resistive input is coupled to the second comparator output, and the second resistive output is coupled to the tuning output.

6. The apparatus of claim 1, wherein the timing circuit includes:
a second transistor having a second control terminal, the second control terminal coupled to the tuning output;
a current source, the current source coupled between a voltage supply terminal and the second transistor, wherein the second transistor is coupled between the current source and a ground terminal;
a comparator having a comparator input and a comparator output, the comparator input coupled to the second transistor and the current source;
a delay circuit having a delay input and a delay output, the delay input coupled to the comparator output; and
an inverter having an inverter input and an inverter output, the inverter input coupled to the delay output, and the inverter output coupled to the fifth tuning input.

7. The apparatus of claim 1, further comprising a second transistor having a second control terminal, the second transistor coupled between the power terminal and a ground terminal, and the second control terminal coupled to the diode, wherein the diode is coupled between the transistor and the second transistor.

8. The apparatus of claim 7, wherein:
the power terminal is a switch terminal of a switched-mode power supply; and
the second transistor is a low-side power transistor of the switched-mode power supply.

9. An apparatus, comprising:
a power terminal at which a voltage is provided; and
a clamp circuit configured to clamp an upper limit of a value range for the voltage to a clamp threshold value, the clamp circuit including:
an avalanche diode;
a tuning circuit having a tuning output and first, second, third, fourth, and fifth tuning inputs, in which the first tuning input is coupled to a sensor input terminal, the second tuning input is coupled to a first sensor threshold terminal, the third tuning input is coupled to a second sensor threshold terminal, the fourth tuning input is coupled to the avalanche diode, the avalanche diode is coupled between the power terminal and the tuning circuit, and the tuning circuit is configured to modify the clamp threshold value responsive to a sensor measurement signal at the sensor input terminal being outside a range bounded by a first sensor threshold signal at the first sensor threshold terminal and a second sensor threshold signal at the second sensor threshold terminal;
a diode;
a transistor having a control terminal, the transistor coupled between the power terminal and the diode, and the control terminal coupled to the tuning output; and
a timeout circuit having a timeout input and a timeout output, in which the timeout input is coupled to the tuning output, the timeout output is coupled to the fifth tuning input, and the timeout circuit is configured to:
detect whether the clamp circuit is clamping the voltage to the clamp threshold value; and
increase the clamp threshold value an amount of time after detecting that the clamp circuit is clamping the voltage to the clamp threshold value.

10. The apparatus of claim 9, wherein the tuning circuit includes:
a first comparator configured to compare the sensor measurement signal to the first sensor threshold signal and provide a first comparison result responsive thereto;
a second comparator configured to compare the sensor measurement signal to the second sensor threshold signal and provide a second comparison result responsive thereto;
a first resistive circuit having a first resistance, in which the tuning circuit is configured to increase or decrease the first resistance responsive to the first comparison result; and
a second resistive circuit having a second resistance, in which the tuning circuit is configured to increase or decrease the second resistance responsive to the second comparison result.

11. The apparatus of claim 10, wherein increasing the first resistance of the first resistive circuit or decreasing the second resistance of the second resistive circuit decreases the clamp threshold value, and decreasing the first resistance of the first resistive circuit or increasing the second resistance of the second resistive circuit increases the clamp threshold value.

12. The apparatus of claim 11, wherein the tuning circuit includes:
a first switching element configured to connect portions of the first resistive circuit together responsive to assertion of the first comparison result to decrease the first resistance; and
a second switching element configured to short a portion of the second resistive circuit responsive to assertion of the second comparison result to decrease the second resistance of the second resistive circuit.

13. The apparatus of claim 10, wherein the timeout circuit is configured to:
monitor the tuning output;
responsive to assertion of a signal at the tuning output, initiate a delay circuit; and
responsive to a programmed delay of the delay circuit expiring, control the tuning circuit to decreases the second resistance of the second resistive circuit.

14. The apparatus of claim 13, wherein to decrease the second resistance of the second resistive circuit, the tuning circuit includes a switching element configured to short a portion of the second resistive circuit responsive to the control of the timeout circuit to decrease the second resistance of the second resistive circuit.

15. A system, comprising:
a switched-mode power supply, including:
a low-side transistor having a power control terminal, the low-side transistor coupled between a switch terminal and a ground terminal; and
a clamp circuit, including:
an avalanche diode;
a tuning circuit having a tuning output and first, second, third, fourth, and fifth tuning inputs, in which the first tuning input is coupled to a sensor input terminal, the second tuning input is coupled to a first sensor threshold terminal, the third tuning input is coupled to a second sensor threshold terminal, and the fourth tuning input is coupled to the avalanche diode, wherein the avalanche diode is coupled between the switch terminal and the tuning circuit;
a diode;
a transistor having a control terminal, the transistor coupled between the power control terminal and the diode, the control terminal coupled to the tuning output, and the diode coupled between the transistor and the power control terminal; and
a timeout circuit having a timeout input and a timeout output, the timeout input coupled to the tuning output and the timeout output coupled to the fifth tuning input.

16. The system of claim 15, wherein the tuning circuit includes:
a first comparator having a first comparator output and first and second comparator inputs, the first comparator input coupled to the sensor input terminal, and the second comparator input coupled to the first sensor threshold terminal;
a second comparator having a second comparator output and third and fourth comparator inputs, the third comparator input coupled to the second sensor threshold terminal, and the fourth comparator input coupled to the sensor input terminal;
a second transistor having a second control terminal, the second control terminal coupled to the first comparator output;
a third transistor having a third control terminal, a source, and a drain, wherein the second transistor is coupled between the third control terminal and a ground terminal;
a first resistor coupled between the source and the third control terminal;
a first capacitor coupled between the source and the third control terminal;
a second resistor;
a third resistor coupled between the second resistor and the ground terminal, in which the second resistor is coupled between the avalanche diode and the third resistor;
a second capacitor coupled between the second resistor and the ground terminal;
a fourth transistor having a fourth control terminal, the fourth control terminal coupled to the second resistor, the third resistor, and the second capacitor;
a first resistive circuit having a first resistive output and first and second resistive inputs, in which the first resistive output is coupled to the tuning output, the third transistor is coupled between the first and second resistive inputs, and the fourth transistor is coupled between the avalanche diode and the first resistive input;
a second resistive circuit having a second resistive output and third, fourth, and fifth resistive inputs, in which the second resistive output is coupled to the tuning output, and the third resistive input is coupled to the ground terminal;
a fifth transistor having a fifth control terminal, the fifth transistor coupled between the fourth resistive input and ground, and the fifth control terminal coupled to the second comparator output; and
a sixth transistor having a sixth control terminal, the sixth transistor coupled between the fifth resistive input and ground, and the sixth control terminal coupled to the timeout output.

17. The system of claim 16, wherein:
the first resistive circuit includes:
a fourth resistor coupled between the source and the drain; and
a fifth resistor coupled between the drain and the tuning output; and
the second resistive circuit includes:
a sixth resistor coupled between the tuning output and the fifth resistive input;
a seventh resistor coupled between the fifth resistive input and the fourth resistive input; and
an eighth resistor coupled between the fourth resistive input and the third resistive input.

18. The system of claim 15, wherein the tuning circuit includes:
a first comparator having a first comparator output and first and second comparator inputs, the first comparator input coupled to the sensor input terminal, and the second comparator input coupled to the first sensor threshold terminal;
a second comparator having a second comparator output and third and fourth comparator inputs, the third comparator input coupled to the second sensor threshold terminal, and the fourth comparator input coupled to the sensor input terminal;
a first resistive circuit having a first resistive output and first and second resistive inputs, in which the first resistive input is coupled to the avalanche diode, the second resistive input is coupled to the first comparator output, and the first resistive output is coupled to the tuning output; and
a second resistive circuit having a second resistive output and third and fourth resistive inputs, in which the third resistive input is coupled to a ground terminal, the fourth resistive input is coupled to the second comparator output, and the second resistive output is coupled to the tuning output.

19. The system of claim 15, wherein the timing circuit includes:
a second transistor having a second control terminal, the second control terminal coupled to the tuning output;
a current source, the current source coupled between a voltage supply terminal and the second transistor, wherein the second transistor is coupled between the current source and a ground terminal;
a comparator having a comparator input and a comparator output, the comparator input coupled to the second transistor and the current source;
a delay circuit having a delay input and a delay output, the delay input coupled to the comparator output; and
an inverter having an inverter input and an inverter output, the inverter input coupled to the delay output, and the inverter output coupled to the fifth tuning input.

20. The system of claim 15, wherein the tuning circuit includes a capacitor coupled between the switch terminal and the tuning output.
